(19) United States
(12) Patent Application Publication
(10) Pub. No.: US 2016/0049383 A1
(43) Pub. Date: Feb. 18, 2016

(54) DEVICE AND METHOD FOR AN INTEGRATED ULTRA-HIGH-DENSITY DEVICE

(71) Applicant: Invensas Corporation, San Jose, CA (US)

(72) Inventors: Charles G. Woychik, San Jose, CA (US); Cyprian Emeka Uzoh, San Jose, CA (US); Hong Shen, San Jose, CA (US); Christopher W. Lattin, San Jose, CA (US); Guilian Gao, San Jose, CA (US); Rajesh Katkar, San Jose, CA (US)

(21) Appl. No.: 14/532,806

(22) Filed: Nov. 4, 2014

Related U.S. Application Data
(60) Provisional application No. 62/036,565, filed on Aug. 12, 2014.

(51) Int. Cl. H01L 25/065; H01L 23/367; H01L 21/56; H01L 23/31; H01L 25/00; H01L 23/00

(52) U.S. Cl. CPC H01L 25/0652; H01L 25/50; H01L 24/17; H01L 24/81; H01L 21/563; H01L 23/3107; H01L 23/3675; H01L 2224/0231; H01L 2224/16235; H01L 2225/06513; H01L 2225/06517; H01L 2225/06555; H01L 2225/06589

(57) ABSTRACT

A device and method for an integrated device includes a first redistribution layer comprising one or more first conductors, one or more first dies mounted to a first surface of the first redistribution layer and electrically coupled to the first conductors, one or more first posts having first ends attached to the first dies and second ends opposite the first ends, one or more second posts having third ends attached to the first surface of the first redistribution layer and fourth ends opposite the third ends, and a second redistribution layer comprising one or more second conductors, the second redistribution layer being attached to the second ends of the first posts and to the fourth ends of the second posts. In some embodiments, the integrated device further includes a heat spreader mounted to a second surface of the first redistribution layer. The second surface is opposite the first surface.

### RELATED APPLICATIONS

The present application claims priority to U.S. Provisional Application Ser. No. 62/036,565, filed Aug. 12, 2014, the contents of which are hereby incorporated by reference into this application.

### BACKGROUND

The present disclosure relates generally to packaging of integrated circuit devices and more particularly to an integrated ultra-high-density device.

Semiconductor devices, such as display devices, memory devices, processors, application-specific integrated circuits (ASICs), and other chips are typically fabricated in a multi-step process. A large number of devices are initially fabricated on one or more substrates, such as a die. The substrate typically includes at least one layer of a semiconductor material, such as silicon, gallium arsenide, and/or the like. Using various photolithographic, depositing, etching, and/or other semiconductor processes, patterns of one or more layers of semiconductor, metals, dielectrics, and/or the like are formed on the substrate to create various devices, interconnects, and so forth. Multiple semiconductor circuits are then typically integrated into a device by incorporating the multiple semiconductor circuits into a single package.

As devices are called upon to perform an ever greater number of tasks, more and more circuits are being integrated into the same package. To accommodate each additional circuit, the packing of the circuits may increase in complexity. The packaging problem may also be compounded by the desire to maintain or even reduce the size of the final device while simultaneously making the device more robust to thermal, chemical, and/or physical stresses. Thus, it may become challenging to incorporate the desired circuits into a single package while still being able to shed excess heat generated by the circuits and simultaneously give the package suitable strength as well as protection from chemical contaminants, such as moisture, without having to appreciably increase the size and/or weight of the device.

Accordingly, it would be desirable to have improved methods for the integrated packaging of devices with ultra-high-density while still providing thermal, chemical, and physical protection for the device.

### SUMMARY

According to some embodiments, an integrated device includes a first redistribution layer comprising one or more first conductors, one or more first dies mounted to a first surface of the first redistribution layer and electrically coupled to the first conductors, one or more first posts having first ends attached to the first dies and second ends opposite the first ends, one or more second posts having third ends attached to the first surface of the first redistribution layer and fourth ends opposite the third ends, and a second redistribution layer comprising one or more second conductors, the second redistribution layer being attached to the second ends of the first posts and to the fourth ends of the second posts.

According to some embodiments, a method of packaging an integrated device includes forming a first redistribution layer comprising one or more first conductors, mounting one or more first dies to a first surface of the first redistribution layer, electrically coupling the first dies to the first conductors, attaching first ends of one or more first posts to the first dies, attaching second ends of the first posts to a second redistribution layer comprising one or more second conductors, attaching third ends of one or more second posts to the first surface of the first redistribution layer, attaching fourth ends of the second posts to the second redistribution layer, mounting one or more second dies to the second redistribution layer opposite the first and second posts, and mounting a display to the second redistribution layer opposite the first and second posts. The second ends are opposite the first ends. And the fourth ends are opposite the third ends;

According to some embodiments, a method of packaging an integrated device includes forming a first redistribution layer comprising one or more first conductors, mounting one or more first dies to a first surface of the first redistribution layer, electrically coupling the first dies to the first conductors, attaching first ends of one or more first posts to the first dies, attaching second ends of the first posts to a first heat spreader, attaching third ends of one or more second posts to the first surface of the first redistribution layer, attaching fourth ends of the second posts to the first heat spreader, locating an open-cavity wafer between the first redistribution layer and the first heat spreader, mounting a second heat spreader to a second surface of the first redistribution layer, mounting one or more second dies to the second surface of the first redistribution layer through one or more holes in the first heat spreader, electrically coupling the second dies to the first conductors, and mounting a first display to the second surface of the first redistribution layer. The second ends are opposite the first ends. The fourth ends are opposite the third ends. The open-cavity wafer surrounds the first dies, the first posts, and the second posts. And the second surface is opposite the first surface

According to some embodiments, the integrated ultra-high-density devices (I-UHDDs) of the present application provide one or more benefits over prior packaging approaches. In some examples, the advantages may include rigid double-sided stiffened packaging substrates having through conductor vias and good matching between the various coefficients of thermal expansion. In some examples, the advantages may further include embedded circuits taking advantage of 2.5D and 3D packaging techniques. In some examples, the advantages may include the ability to dissipate heat from both sides of the I-UHDDs. In some examples, the advantages may further include support for high-density metallization, including metallization with lines and/or spaces of 5 μm or smaller in size. In some examples, the advantages may further include packaging with hermetic sealing to protect the packaged circuits from chemical and/or other environmental contaminants. In some examples, the advantage may further include packaging suitable for use in double-sided displays.

### BRIEF DESCRIPTION OF THE DRAWINGS

FIG. 1 is a simplified diagram of an integrated ultra-high-density device according to some embodiments.

FIG. 2 is a simplified diagram of a method of manufacturing the integrated ultra-high-density device of FIG. 1 according to some embodiments.

FIGS. 3A-3J are simplified diagrams of the partially formed integrated ultra-high-density device of FIG. 1.

FIG. 4 is a simplified diagram of another integrated ultra-high-density device according to some embodiments.

FIG. 5 is a simplified diagram of another integrated ultra-high-density device according to some embodiments.

FIG. 6 is a simplified diagram of a method of manufacturing the integrated ultra-high-density devices of FIGS. 4 and 5 according to some embodiments.

FIGS. 7A-7E are simplified diagrams of the partially formed integrated ultra-high-density devices of FIGS. 4 and 5.

In the figures, elements having the same designations have the same or similar functions.

### DETAILED DESCRIPTION

In the following description, specific details are set forth describing some embodiments consistent with the present disclosure. It will be apparent, however, to one skilled in the art that some embodiments may be practiced without some or all of these specific details. The specific embodiments disclosed herein are meant to be illustrative but not limiting. One skilled in the art may realize other elements that, although not specifically described here, are within the scope and the spirit of this disclosure. In addition, to avoid unnecessary repetition, one or more features shown and described in association with one embodiment may be incorporated into other embodiments unless specifically described otherwise or if the one or more features would make an embodiment non-functional.

The present disclosure relates to electronic technology, and more particularly to semiconductor packages. Some embodiments are suitable for use with displays, e.g. flat panel displays (liquid crystal displays (LCD), organic light emitting diode displays (OLED), electronic paper, and others). In some embodiments, the display structure strengthens the dies or wafers which have circuitry driving the display and performing possibly other functions, and the device may or may not have another rigid substrate; some embodiments have no PCB (printed circuit board). In some embodiments, high ability to dissipate heat is provided through different sides of the device. Other embodiments are also provided.

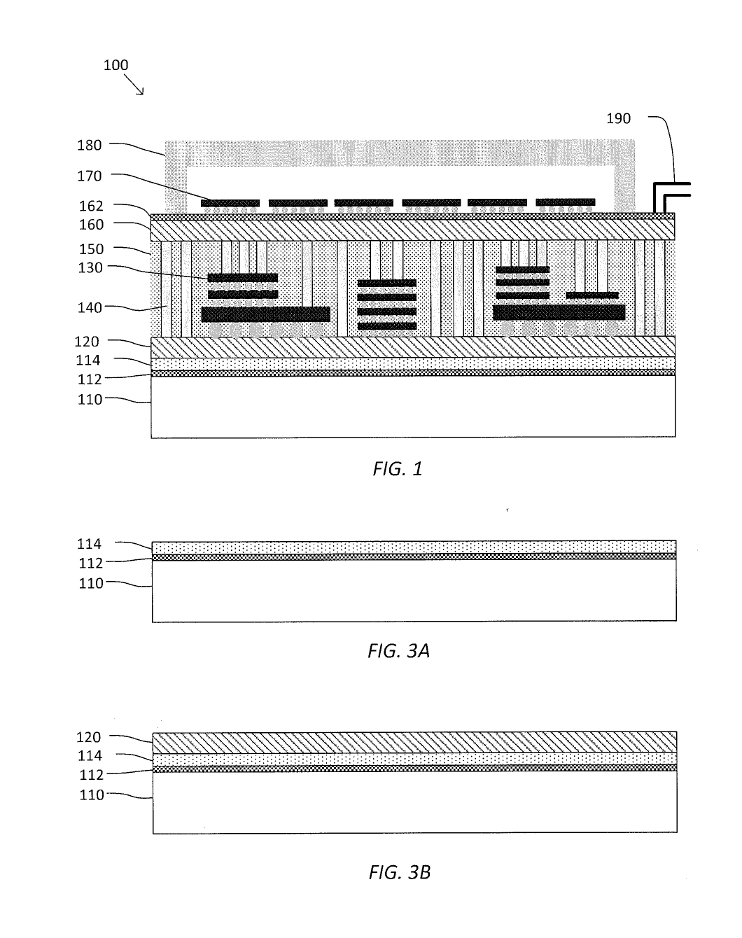

FIG. 1 is a simplified diagram of an integrated ultra-high-density device (I-UHDD) 100 according to some embodiments. As shown in FIG. 1, I-UHDD 100 is formed on a substrate 110. Substrate 110 may include any suitable material on which one or more semiconductor devices and/or circuits may be mounted. In some examples, substrate 110 may include any suitable material, such as glass, silicon, gallium arsenide, ceramic, composites, and/or the like. In some examples, substrate 110 may include a rigid and/or semi-rigid material that may provide suitable stiffness and/or physical strength to I-UHDD 100. In some examples, substrate 110 may include one or more materials with a low coefficient of thermal expansion.

In some embodiments, an optional etch stop layer 112 may be formed on substrate 110. In some examples, etch stop layer 112 may include silicon nitride, silicon carbide, and/or another suitable material. In some examples, etch stop layer 112 may be used to protect substrate 110 during fabrication of other portions of I-UHDD 100. In some examples, etch stop layer 112 is optional and may be omitted.

In some embodiments, an optional compliant layer 114 may be formed on etch stop layer 112. In some examples, compliant layer 114 may include a high thermal resistance material, such as polyimide, and/or the like. In some examples, compliant layer 114 may be resistant to high temperatures. In some examples, compliant layer 114 may help reduce thermal stresses in I-UHDD 100 by having a coefficient of thermal expansion between the coefficient of thermal expansion for substrate 110 and the materials in other portions of I-UHDD 100. In some examples, when etch stop layer 112 is omitted, compliant layer 114 may be formed on substrate 110. In some examples, compliant layer 114 is optional and may be omitted.

A first redistribution layer (RDL) 120 is formed on substrate 110, etch stop layer 112, and/or compliant layer 114 depending upon whether etch stop layer 112 and/or compliant layer 114 are used in I-UHDD 100. The first RDL 120 includes a network of conductive lines and/or layers of metallization separated by one or more insulating and/or dielectric layers. In some examples, the first RDL 120 may be formed using the methods and/or materials discussed in U.S. Provisional Application Ser. No. 61/952,066, filed Mar. 12, 2014, entitled “Integrated Circuit Assemblies and Methods of Fabrication,” which is hereby incorporated by reference into this application.

One or more integrated circuit dies 130 are mounted on the first RDL 120. The dies 130 may be mounted on the first RDL 120 singly or in one or more stacks using a combination of solder balls, pads, bond wires, and/or the like so that the circuitry on each of the dies 130 may be electrically interconnected using the network of conductive lines in the first RDL 120. Although not shown, in some examples, one or more interposers and/or semiconductor packages may be used to mount the dies 130 and/or create the stacks. In some examples, one or more of the dies 130 may include through silicon vias (TSVs) and/or other circuitry permitting electrical connections to be formed between each of the dies 130 in a stack and/or between the dies 130 separated from the first RDL 120 by one or more others of the dies 130.

One or more posts and/or electrically conductive pathways 140 may be attached to the tops of the dies 130 and/or the top of the first RDL 120. In some examples, one or more of the posts 140 may be metal posts. In some examples, one or more of the posts 140 may be metal studs and/or bond wires as described in Invensas™ High Performance BVA PoP package for Mobile Systems, May 2013 by Invensas Corporation of San Jose, Calif., and incorporated herein by reference. In some examples, one or more of the posts 140 may be wire bonds similar to those described in U.S. Pat. No. 8,618,659 issued Dec. 31, 2013 to Sato et al. and incorporated by reference into this application. In some examples, one or more of the posts 140 may be copper pillars, copper micropillars, and/or the like. In some examples, one or more of the posts 140 may be non-metallic. In some examples, one or more of the posts 140 may not be connected to a contact, electrical pad, electrical pathway, and/or the like on any of the dies 130 and/or the first RDL 120.

According to some embodiments, the posts 140 may enhance the thermal, electrical, and/or physical characteristics of I-UHDD 100. In some examples, the posts 140 may be used to provide heat dissipation throughout I-UHDD 100 by, for example, dissipating heat away from one or more of the dies 130. In some examples, the posts 140 may be used to perform electrical connections within I-UHDD 100 when the posts 140 are electrically conductive and are mounted to the exposed TSVs in the dies 130 and/or to exposed portions of the conductive lines in the first RDL 120. In some examples, one or more of the posts 140 may help distribute power supply voltages and/or grounds throughout I-UHDD 100. In some examples, the posts 140 may provide structural stability and/or stiffness to I-UHDD 100. In some examples, different ones of the posts 140 may be used for different purposes depending upon the locations of the posts 140 and the various circuits located in the dies 130 and elsewhere in I-UHDD 100. In some examples, the different purposes may include one or more of structural stability, thermal conductivity, and/or electrical conductivity. In some examples, different ones of the posts 140 may have different diameters, cross-sectional areas, and/or the like depending upon the structure, thermal, and/or electrical properties desired for the respective posts 140. In some examples, more and/or fewer of the posts 140 may be used in different regions of I-UHDD 100. In some examples, the posts 140 may be mounted to the tops of the dies 130 and/or the first RDL 120 using solder, one or more adhesives, and/or the like. In some examples, the one or more adhesives may be thermally and/or electrically conductive.

In some embodiments, an optional underfill and/or encapsulant 150 may be present between the posts 140 and/or the dies 130. In some examples, encapsulant 150 may provide additional structural support to I-UHDD 100 and/or may help maintain the locations of the dies 130. In some examples, encapsulant 150 may be a flowawable compound, such as an epoxy resin, a polyimide, and/or the like. In some examples, encapsulant 150 may be a porous compound, such as a porous polyimide and/or the like. In some examples, encapsulant 150 may be applied by injection, molding, and/or spin-on coating. In some examples, encapsulant 150 may be cured after it is applied. In some examples, encapsulant 150 is optional and may be omitted.

The upper ends of the posts 140 are mounted to a second RDL 160. Like the first RDL 120, the second RDL 160 includes a network of conductive lines and/or layers of metallization separated by one or more insulating and/or dielectric layers. In some examples, the second RDL 160 may be formed using the methods and/or materials discussed in U.S. Provisional Application Ser. No. 61/952,066, filed Mar. 12, 2014, entitled “Integrated Circuit Assemblies and Methods of Fabrication,” which is hereby incorporated by reference into this application. Additionally, each of the posts 140 may be structurally, thermally, and/or electrically coupled to the second RDL 160 depending on whether the respective posts 140 are being used for structural, thermal, and/or electrical purposes. In some examples, the second RDL 160 may be formed on top of encapsulant 150.

In some embodiments, an optional non-conductive layer 162 may be fonned on the second RDL 160. In some examples, the non-conductive layer 162 may include an underfill material deposited on the second RDL 160. In some examples, the non-conductive layer 162 may include a non-conductive film, dielectric layer, and/or the like formed on the second RDL 160. In some examples, the non-conductive layer 162 may be used to protect the second RDL 160 from accidental electrical shorts, chemical contamination, and/or the like. In some examples, the non-conductive film 162 is optional and may be omitted.

One or more top-level dies 170 are mounted on the top surface of the second RDL 160. In some examples, the top-level dies 170 may be mounted to contact pads located on the top surface of the second RDL 160 so that the top-level dies 170 may be coupled to other circuits in I-UHDD 100 through the conductive lines located in the second RDL 160. In some examples, the top-level dies 170 may be mounted on the second RDL 160 using a combination of solder balls, bond wires, and/or the like. In some examples, one or more of the top-level dies 170 may include an image sensor.

A display 180 is mounted on the non-conductive layer 162. Display 180 includes a cavity that accommodates the top-level dies 160. In some examples, electrical signals driving display 180 may be provided to display 180 using one or more conductors located in the sides of display 180. In some examples, the conductors may be coupled to corresponding contact pads of the conductive lines of the second RDL 160 exposed via openings in the non-conductive layer 162. In some examples, when the non-conductive layer 162 is omitted, display 180 may be mounted on the second RDL 160. In some examples, the display 180 may have one or more recesses or cavities (not shown) for the disposition of additional active and/or passive devices (not shown).

In some embodiments, an optional connector 190 may be included to connect I-UHDD 100 to other devices and/or circuits. In some examples, the other devices and/or circuits may include a slot in a computing device, an antenna, a battery, a power supply, a bus, and/or the like. In some examples, conductors in connector 190 may be coupled to the conductive lines of the second RDL 160. In some examples, connector 190 is optional and may be omitted.

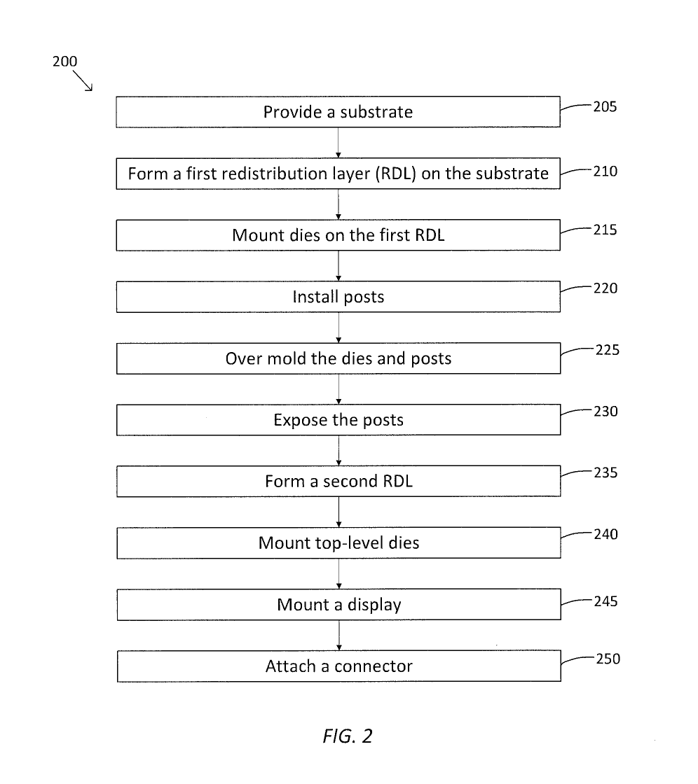

FIG. 2 is a simplified diagram of a method 200 of manufacturing an integrated ultra-high-density device (I-UHDD) according to some embodiments. Processes 205-250 of method 200 are representative only, and one of ordinary skill in the art would understand that variations in processes 205-250 are possible including performing processes 205-250 in different orders, concurrently, and/or the like. In some embodiments, one or more of the processes 225, 230, and/or 250 are optional and may be omitted. In some embodiments, method 200 may be used to manufacture I-UHDD 100 of FIG. 1, although one of ordinary skill would understand how method 200 may be applied to form other devices than I-UHDD 100.

At a process 205, a substrate is provided. In some embodiments, the substrate may be consistent with substrate 110. In some examples, the substrate may be shaped and/or formed using one or more deposition, etching, and/or other semiconductor fabrication techniques. In some examples, the substrate may include any suitable material on which one or more semiconductor devices and/or circuits may be mounted. In some examples, the substrate may include glass, silicon, gallium arsenide, ceramic, composites, and/or the like. In some examples, the substrate may include a rigid and/or semi-rigid material that may provide suitable stiffness and/or physical strength to the I-UHDD. In some examples, the substrate may include one or more materials with a low coefficient of thermal expansion.

In some embodiments, the substrate may include an optional etch stop layer. In some embodiments, the etch stop layer may be consistent with the etch stop layer 112. In some examples, the etch stop layer may be formed on the substrate using one or more deposition and/or etching processes. In some examples, the etch stop layer may include one or more layers of silicon nitride, silicon carbide, and/or another suitable material. In some examples, the etch stop layer may be used to protect the substrate during subsequent processes of method 200.

In some embodiments, the substrate may further include an optional compliant layer. In some embodiments, the compliant layer may be consistent with compliant layer 114. In some examples, the compliant layer may be formed on the substrate and/or the etch stop layer using one or more deposition and/or etching processes. In some examples, the compliant layer may include a high thermal resistance material, such as polyimide, and/or the like. In some examples, the compliant layer may be resistant to high temperatures. In some examples, the compliant layer may help reduce thermal stresses in the I-UHDD by having a coefficient of thermal expansion between the coefficient of thermal expansion for the substrate and the materials in other portions of the I-UHDD.

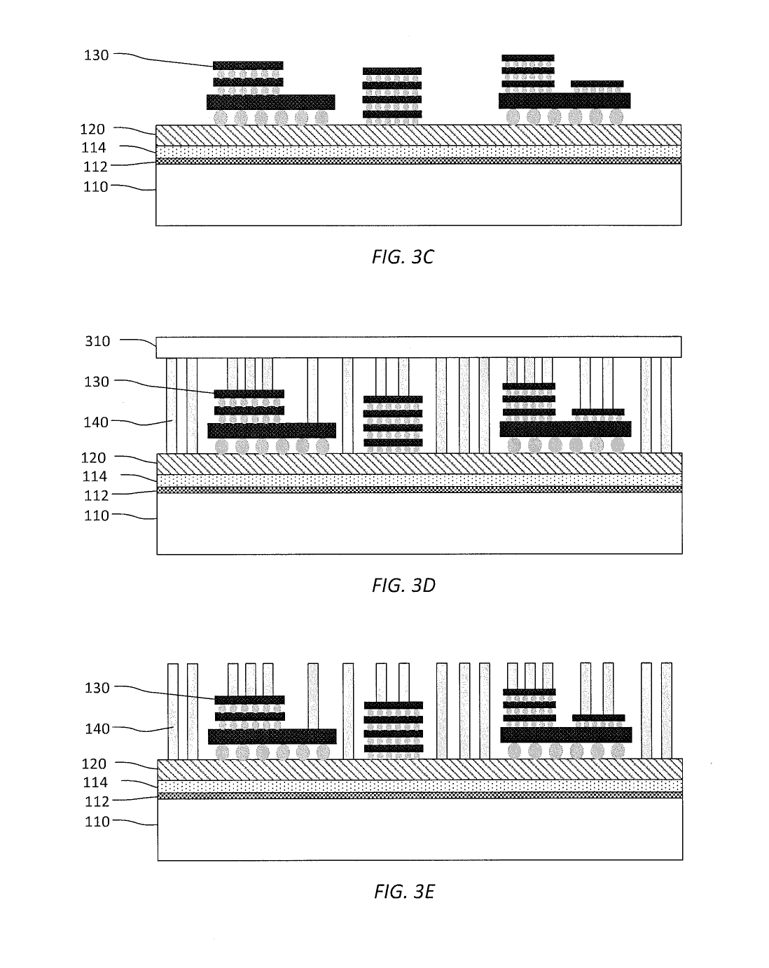

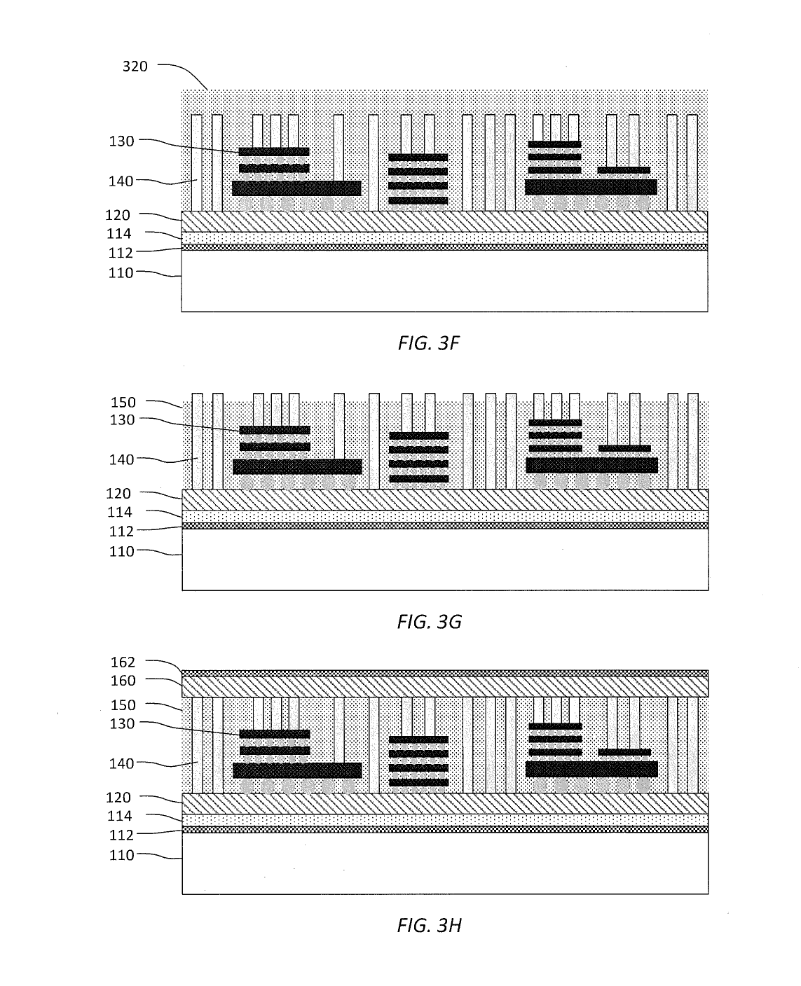

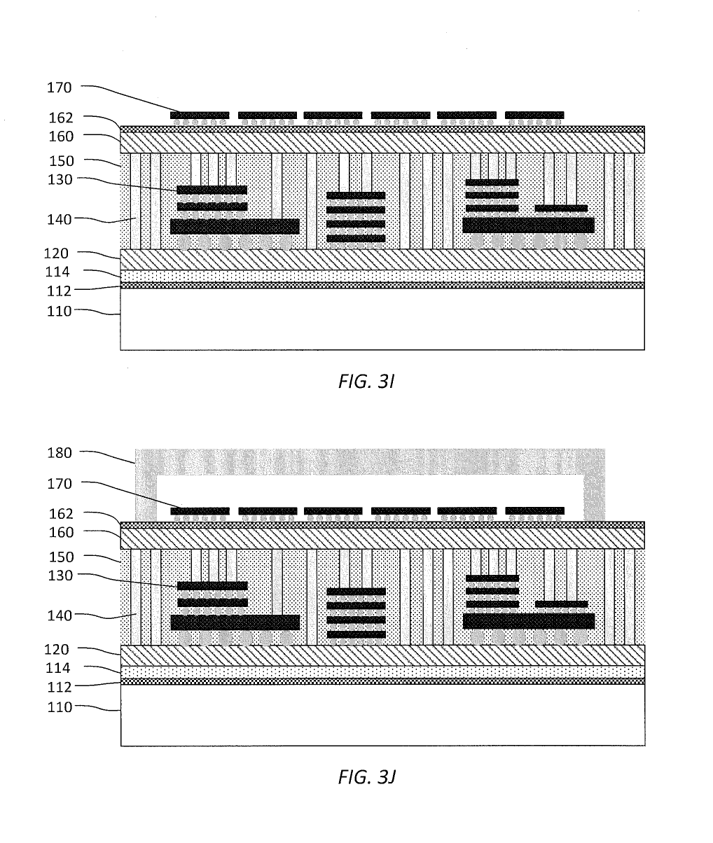

FIG. 3A is a simplified diagram of the partially formed I-UHDD of FIG. 1 after completion of process 205. FIG. 3A shows the substrate 110 with both the optional etch stop layer 112 and the optional compliant layer 114 formed thereon.

At a process 210, a first RDL is formed on the substrate. In some embodiments, the first RDL may be consistent with the first RDL 120. In some examples, the first RDL may be formed on the substrate, the etch stop layer, and/or the compliant layer using one or more deposition and/or etching processes. In some examples, the one or more deposition and/or etching processes may be used to form a network of conductive lines and/or layers of metallization separated by one or more insulating and/or dielectric layers in the first RDL. In some examples, the first RDL may be formed using the methods and/or materials discussed in U.S. Provisional Application Ser. No. 61/952,066, filed Mar. 12, 2014, entitled “Integrated Circuit Assemblies and Methods of Fabrication,” which is hereby incorporated by reference into this application.

FIG. 3B is a simplified diagram of the partially formed I-UHDD of FIG. 1 after completion of process 210. FIG. 3B shows the first RDL 120 formed on the optional compliant layer 114.

At a process 215, one or more dies are mounted on the first RDL. In some embodiments, the dies may be consistent with the dies 130. In some examples, the dies may be mounted on the first RDL singly or in one or more stacks using a combination of solder balls, pads, bond wires, and/or the like so that the circuitry on each of the dies may be electrically interconnected using the network of conductive lines in the first RDL. In some examples, one or more interposers and/or semiconductor packages may be used to mount the dies to the first RDL and/or create the stacks where one of the dies is mounted on another of the dies. In some examples, one or more soldering and/or bonding processes may be used to mount the dies. In some examples, one or more of the stacks of dies may be formed by mounting the dies one layer at a time to the respective stacks. In some examples, one or more of the stacks of dies may be partially and/or fully pre-stacked before being mounted to the first RDL. In some examples, the one or more dies may be stacked in such a fashion that electrical connections may be formed between each of the dies in the respective stacks and/or to the first RDL. In some examples, the electrical connections may include one or more TSVs.

FIG. 3C is a simplified diagram of the partially formed I-UHDD of FIG. 1 after completion of process 215. FIG. 3C shows the one or more dies 130 mounted to the first RDL 120 using a plurality of stacks.

At a process 220, posts are installed. In some embodiments, the posts may be consistent with posts 140. In some embodiments, the posts may be initially formed and/or attached to a sacrificial carrier wafer and/or holding substrate 310. In some examples, the posts may be formed on the holding substrate 310 using one or more deposition and/or etching processes. In some examples, the posts may be attached the holding substrate 310 using one or more adhesives and/or adhesive layers. In some examples, positions and/or lengths of the posts may be controlled to match the positions and heights of the various stacks of dies mounted to the first RDL. In some examples, one or more of the posts may be metal posts. In some examples, one or more of the posts may be metal studs and/or bond wires as described in Invensas™ High Performance BVA PoP package for Mobile Systems, May 2013 by Invensas Corporation of San Jose, Calif., and incorporated herein by reference. In some examples, one or more of the posts may be wire bonds similar to those described in U.S. Pat. No. 8,618,659 issued Dec. 31, 2013 to Sato et al. and incorporated by reference into this application. In some examples, one or more of the posts may be copper pillars, copper micropillars, and/or the like. In some examples, one or more of the posts may be non-metallic. In some examples, different ones of the posts may have different diameters, cross-sectional areas, and/or the like depending upon the structure, thermal, and/or electrical properties desired for the respective posts. In some examples, more and/or fewer of the posts may be used in different regions of the I-UHDD.

In some examples, the posts and holding substrate 310 may then be mounted as a single unit to the first RDL and/or the stacks of dies. In some examples, one or more of the posts may be attached to the tops of the dies and/or the top of the first RDL. In some examples, the posts may be mounted to the tops of the dies and/or the first RDL using solder, one or more adhesives, and/or the like. In some examples, the one or more adhesives may be thermally and/or electrically conductive. FIG. 3D is a simplified diagram of the partially formed I-UHDD of FIG. 1 after the posts 140 and the holding substrate 310 are mounted to the stacks of dies 130 and the first RDL 120 during process 220.

After the posts are mounted to the stacks of dies and the first RDL 120, the holding substrate 310 is removed. In some examples, when the posts are attached to the holding substrate 310 using one or more adhesives, the holding substrate may be separated from the posts by deactivating the adhesives. In some examples, the adhesives may be deactivating by hardening the adhesives by applying heat, such as through baking and/or use of a laser beam. In some examples, the adhesives may be decoupled between the first RDL 120 and the holding substrate 310 using ultraviolet radiation. In some examples, once the adhesives lose their adhesion properties, the holding substrate 310 may be removed. In some examples, the holding substrate 310 may be removed by using one or more etching, chemical-mechanical planarization (CMP), and/or grinding processes to remove the material of the holding substrate 310. FIG. 3E is a simplified diagram of the partially formed I-UHDD of FIG. 1 after the holding substrate 310 is removed from the posts 140 during process 220.

At an optional process 225, the dies and posts are over molded. In some embodiments, an optional underfill and/or encapsulant 320 may be molded over the posts, the stacked dies, and/or the first RDL. In some examples, the encapsulant may be a flowawable compound, such as an epoxy resin, a polyimide, and/or the like. In some examples, the encapsulant may be a porous compound, such as a porous polyimide and/or the like. In some examples, the encapsulant may be applied by injection, molding, and/or spin-on coating. In some examples, the encapsulant may be cured after it is applied.

FIG. 3F is a simplified diagram of the partially formed I-UHDD of FIG. 1 after completion of process 225. FIG. 3F shows the encapsulant 320 molded over the posts 140, the stacked dies 130, and the first RDL 120.

At an optional process 230, the posts are exposed. In some embodiments, a portion of the encapsulant 320 may be removed to expose the tops of the posts so that they may be electrically and/or thermally connected to additional layers of the I-UHDD. In some examples, the portion of the encapsulant 320 may be removed by thinning through the use of one or more etching, blasting, CMP, and/or grinding processes.

FIG. 3G is a simplified diagram of the partially formed I-UHDD of FIG. 1 after completion of process 230. FIG. 3G shows the encapsulant 320 partially removed to form the encapsulant 150 and expose the tops of the posts 140. Although FIG. 3G shows that an upper portion of the posts 140 are exposed, one of ordinary skill in the art would understand that more or less of the tops of the posts 140 may be exposed including exposing the top edges and not the sides of the posts 140.

At a process 235, a second RDL is formed. In some embodiments, the second RDL may be consistent with the second RDL 160. In some examples, the exposed upper ends of the posts are mounted to a second RDL 160. In some examples, the second RDL may be formed on the thinned encapsulant using one or more deposition and/or etching processes. In some examples, one or more deposition and/or etching processes may be used to form a network of conductive lines and/or layers of metallization separated by one or more insulating and/or dielectric layers in the second RDL. In some examples, the second RDL may be formed using the methods and/or materials discussed in U.S. Provisional Application Ser. No. 61/952,066, filed Mar. 12, 2014, entitled “Integrated Circuit Assemblies and Methods of Fabrication,” which is hereby incorporated by reference into this application. Additionally, each of the exposed posts may be structurally, thermally, and/or electrically coupled to the second RDL depending on whether the respective posts are being used for structural, thermal, and/or electrical purposes. In some examples, the exposed tops of the posts may be mounted to one or more bonding pads of the second RDL. In some examples, solder and/or one or more electrical and/or thermally conductive adhesives may be used to mount the tops of the posts to the second RDL.

In some embodiments, an optional non-conductive layer may be formed on the second RDL. In some embodiments, the non-conductive layer may be consistent with the non-conductive layer 162. In some examples, the non-conductive layer may be deposited on the second RDL in the form of an underfill material. In some examples, one or more non-conductive films, dielectric layers, and/or the like may be formed on the second RDL using one or more deposition and/or etching processes. In some examples, the non-conductive layer may be used to protect the second RDL from accidental electrical shorts, chemical contamination, and/or the like.

FIG. 3H is a simplified diagram of the partially formed I-UHDD of FIG. 1 after completion of process 235. FIG. 3H shows the second RDL 160 and the optional non-conductive layer 162 formed on the top of the posts 140 and the encapsulant 150.

At a process 240, top-level dies are mounted on the second RDL and/or the non-conductive layer. In some embodiments, the top-level dies may be consistent with the top-level dies 170. In some examples, the top-level dies may be mounted on the second RDL and/or the non-conductive layer using a combination of solder balls, pads, bond wires, and/or the like so that the circuitry on each of the top-level dies may be electrically interconnected using the network of conductive lines in the second RDL. In some examples, one or more soldering and/or bonding processes may be used to mount the top-level dies.

FIG. 3I is a simplified diagram of the partially formed I-UHDD of FIG. 1 after completion of process 240. FIG. 3I shows the top-level dies 170 mounted on the second RDL 160 and/or the optional non-conductive layer 162.

At a process 245, a display is mounted. In some examples, the display may be consistent with the display 180. In some examples, the display may include a cavity that accommodates the top-level dies. In some examples, electrical signals driving the display may be provided to the display using one or more conductors located in the sides of the display. In some examples, the conductors may be coupled to corresponding contact pads of the conductive lines of the second RDL exposed via openings in the non-conductive layer. In some examples, the conductors of the display may be coupled to the corresponding contact pads using one or more soldering and/or bonding processes.

FIG. 3J is a simplified diagram of the partially formed I-UHDD of FIG. 1 after completion of process 245. FIG. 3J shows the display 170 mounted on the second RDL 160 and/or the optional non-conductive layer 162.

At an optional process 250, a connector is attached. In some embodiments, the connector may be consistent with the connector 190. In some examples, the connector may be attached to the second RDL and/or the non-conductive layer using one or more soldering and/or bonding processes so that one or more of the conductive lines in the second RDL may be coupled to other devices and/or circuits, such as a slot in a computing device, an antenna, a battery, a power supply, a bus, and/or the like.

Upon completion of method 200, the I-UHDD 100 may be completed as shown in FIG. 1.

As discussed above and further emphasized here, FIGS. 2 and 3A-3J are merely examples which should not unduly limit the scope of the claims. One of ordinary skill in the art would recognize many variations, alternatives, and modifications. In some embodiments, the second RDL may be formed and mounted to the tops of the posts using other processes. In some examples, the second RDL may be formed on the bottom of the holding substrate 310 so that the posts are attached and/or formed on the second RDL. Under this approach, the process 235 may be used to form the second RDL on the holding substrate 310 with both the posts and the second RDL being installed together during process 220. In some examples, the holding substrate 310 may then be removed from the second RDL by deactivating the adhesive used to attach the second RDL to the holding substrate 310 or removing the holding substrate 310 by thinning using one or more etching, CMP, and/or grinding processes. In some examples, the thinning of the holding substrate 310 may expose one or more contact pads in the second RDL to which the top-level dies are mounted. In some examples, the holding substrate 310 may be omitted with the second RDL acting as the carrier substrate for the posts. In some examples, the encapsulant may then be injected between the first RDL and the second RDL.

In some embodiments, reduced amounts of the encapsulant may be used during process 225. In some examples, the encapsulant added during process 225 may be limited so that it partially fills the area between the first RDL and the tops of the posts. In some examples, the partial filling leaves the tops of the posts exposed so that process 230 may be omitted. In some examples, the partial filling may leave one or more areas between the first RDL and the second RDL with no encapsulant.

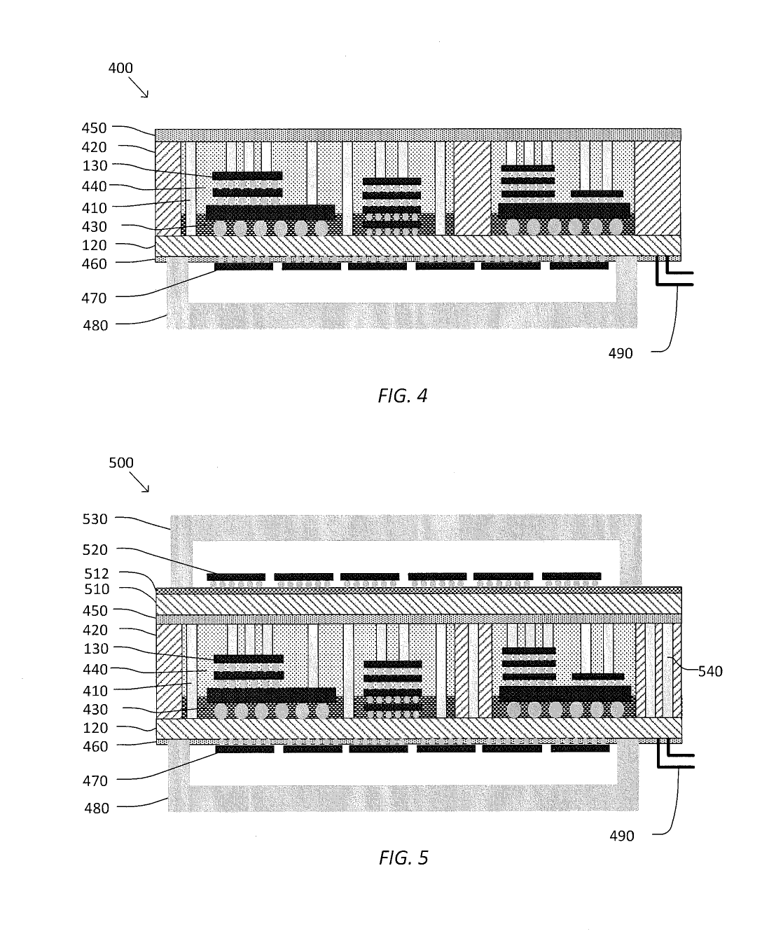

FIG. 4 is a simplified diagram of another integrated ultra-high-density device (I-UHDD) 400 according to some embodiments. As shown in FIG. 4, I-UHDD 400 includes several similarities to I-UHDD 100 from FIG. 1. Similar to I-UHDD 100, I-UHDD 400 is formed around a first RDL 120. The first RDL 120 includes a network of conductive lines and/or layers of metallization separated by one or more insulating and/or dielectric layers. In some examples, the first RDL 120 may be formed using the methods and/or materials discussed in U.S. Provisional Application Ser. No. 61/952,066, filed Mar. 12, 2014, entitled “Integrated Circuit Assemblies and Methods of Fabrication,” which is hereby incorporated by reference into this application.

One or more integrated circuit first dies 130 are mounted on the first RDL 120. The first dies 130 may be mounted on the first RDL 120 singly or in one or more stacks using a combination of solder balls, pads, bond wires, and/or the like so that the circuitry on each of the first dies 130 may be electrically interconnected using the network of conductive lines in the first RDL 120. Although not shown, in some examples, one or more interposers and/or semiconductor packages may be used to mount the first dies 130 and/or create the stacks. In some examples, one or more of the first dies 130 may include through silicon vias (TSVs) and/or other circuitry permitting electrical connections to be formed between each of the first dies 130 in a stack and/or between the first dies 130 separated from the first RDL 120 by one or more others of the first dies 130.

One or more posts and/or electrically conductive pathways 410 may be attached to the tops of the first dies 130 and/or the top of the first RDL 120. In some examples, one or more of the posts 410 may be metal posts. In some examples, one or more of the posts 410 may be metal studs and/or bond wires as described in Invensas™ High Performance BVA PoP package for Mobile Systems, May 2013 by Invensas Corporation of San Jose, Calif., and incorporated herein by reference. In some examples, one or more of the posts 410 may be wire bonds similar to those described in U.S. Pat. No. 8,618,659 issued Dec. 31, 2013 to Sato et al. and incorporated by reference into this application. In some examples, one or more of the posts 410 may be copper pillars, copper micropillars, and/or the like. In some examples, one or more of the posts 410 may be non-metallic. In some examples, one or more of the posts 410 may not be connected to a contact, electrical pad, electrical pathway, and/or the like on any of the dies 130 and/or the first RDL 120.

According to some embodiments, the posts 410 may enhance the thermal, electrical, and/or physical characteristics of I-UHDD 400. In some examples, the posts 410 may be used to provide heat dissipation throughout I-UHDD 400 by, for example, dissipating heat away from one or more of the first dies 130. In some examples, the posts 410 may be used to perform electrical connections within I-UHDD 400 when the posts 410 are electrically conductive and are mounted to the exposed TSVs in the first dies 130 and/or to exposed portions of the conductive lines in the first RDL 120. In some examples, one or more of the posts may help distribute power supply voltages and/or grounds throughout I-UHDD 400. In some examples, the posts 410 may provide structural stability and/or stiffness to I-UHDD 400. In some examples, different ones of the posts 410 may be used for different purposes depending upon the locations of the posts 410 and the various circuits located in the first dies 130 and elsewhere in I-UHDD 400. In some examples, the different purposes may include one or more of structural stability, thermal conductivity, and/or electrical conductivity. In some examples, different ones of the posts 410 may have different diameters, cross-sectional areas, and/or the like depending upon the structure, thermal, and/or electrical properties desired for the respective posts 410. In some examples, more and/or fewer of the posts 410 may be used in different regions of I-UHDD 400. In some examples, the posts 410 may be mounted to the tops of the first dies 130 and/or the first RDL 120 using solder, one or more adhesives, and/or the like. In some examples, the one or more adhesives may be thermally and/or electrically conductive.

Although the posts 410 may be substantially similar to the posts 140 of I-UHDD 100, there may typically be fewer in number because an open-cavity wafer 420 may also be mounted on the first RDL 120 and/or in and among the stacks of first dies 130. In some examples, the open-cavity wafer 420 may include one or more through holes to accommodate the locations whether the posts 410 and/or the stacks of dies are mounted to the first RDL 120. In some examples, the open-cavity wafer may include any suitable wafer material such as glass, silicon, gallium arsenide, and/or the like. In some examples, the open-cavity wafer may also be a handle wafer. In some examples, the open-cavity wafer 420 may have a single cavity into which each of the posts 410 and/or the stacks of first dies 130 are located. In some examples, the open-cavity wafer 420 may have multiple openings that separate the posts 410 and/or the stacks of first dies 130 into multiple regions. In some examples, the open-cavity wafer 420 may also provide protection to the posts 410 and/or first dies 130 that it surrounds from environmental contaminants such as gasses, fluids, and chemicals that may be present where the I-UHDD 400 is used. In some examples, the open-cavity wafer 420 may also include one or more circuits that may interconnect to the first RDL 120 and/or to other circuits in I-UHDD 400. In some examples, the open-cavity wafer 420 may also provide structural support to I-UHDD 400.

In some embodiments, an optional underfill 430 may be present between the first RDL 120 and the first dies 130 located at the bottoms of the stacks. In some examples, the underfill 430 may include any suitable underfill material, such as an epoxy resin, an elastomer, and/or the like. In some examples, the underfill 430 may be cured after it is applied. In some examples, underfill 430 is optional and may be omitted.

In some embodiments, an optional encapsulant 440 may be present above the underfill 430 and between the posts 410 and/or the first dies 130. In some examples, encapsulant 440 may be similar to underfill 150 of I-UHDD 100 and may provide additional structural support to I-UHDD 400 and/or may help maintain the locations of the first dies 130. In some examples, encapsulant 440 may be a flowawable compound, such as an epoxy resin, a polyimide, and/or the like. In some examples, encapsulant 440 may be a porous compound, such as a porous polyimide and/or the like. In some examples, encapsulant 440 may be applied by injection, molding, and/or spin-on coating. In some examples, encapsulant 440 may be cured after it is applied. In some examples, encapsulant 440 is optional and may be omitted.

In some examples, encapsulant 440 may not completely fill the openings in the open-cavity wafer completely so that at least the top surfaces of the posts 410 are exposed. In some examples, encapsulant 440 may cover the tops of each of the stacks of dies 410. In some examples, the upper surface of encapsulant 440 may be planarized using one or more etching, grinding, and/or CMP processes.

A first heat spreader 450 may be mounted to the tops of the posts 410. In some examples, the first heat spreader 450 may include one or more materials with a high thermal conductivity, such as pyrolytic graphite, highly-oriented pyrolytic carbon or graphite (HOPG), copper, and/or the like. In some examples, the tops of one or more of the posts 410 may be attached to the first heat spreader 450 using solder, a thermal interface material, and/or one or more thermally conductive adhesives. In some examples, the first heat spreader 450 may also be divided into one or more regions that may be used to provide one or more charge reservoirs for one or more power supplies or reference voltages used by I-UHDD 400. In some examples, the one or more regions of the first heat spreader 450 may be electrically coupled to respective ones of the posts 410 in each of the regions in order to provide access to the charge reservoirs. In some examples, the first heat spreader 450 may also provide other electrical interconnections for I-UHDD 400. In some examples, the first heat spreader 450 may further include one or more through holes (not shown) that may be used to allow one or more of the posts 410 to pass through the first heat spreader 450 to reach circuitry mounted to the opposite side of the first heat spreader 450 as will be described in further detail below.

A second heat spreader 460 may be mounted to the bottom of the first RDL 120. In some examples, the second heat spreader 460 may include one or more materials with a high thermal conductivity, such as pyrolytic graphite, HOPG, copper, and/or the like. In some examples, the second heat spreader 460 may be attached to the first RDL using solder, a thermal interface material, and/or one or more thermally conductive adhesives. In some examples, the second heat spreader 460 may further include one or more through holes providing exposure to contact pads located on the bottom of the first RDL 120. In some examples, the second heat spreader 460 may be coupled to one or more of the contact pads on the first RDL 120, thus electrically coupling the second heat spreader 460 to the network of conductive lines located in the first RDL 120. In some examples, the second heat spreader 460 may also be divided into one or more regions that may be used to provide one or more charge reservoirs for one or more power supplies or reference voltages used by I-UHDD 400. In some embodiments, the bottom of the first RDL 120 may also include one or more dielectric layers to prevent unwanted electrical shorting between the first RDL 120 and the second heat spreader 460.

One or more second dies 470 are mounted through the through holes in the second heat spreader 460 to the contact pads on the bottom of the first RDL 120. In some examples, the second dies 470 may be mounted to the first RDL 120 using a combination of solder balls, bond wires, and/or the like. In some examples, an optional underfill may be used between the second heat spreader 460 and the second dies 470. In some examples, one or more of the second dies 470 may include an image sensor.

A display 480 is also mounted to bottom of the first RDL 120 and/or the second heat spreader 460. Display 480 includes a cavity that accommodates the second dies 470. In some examples, electrical signals driving display 480 may be provided to display 480 using one or more conductors located in the sides of display 480. In some examples, the conductors may be coupled to corresponding contact pads of the conductive lines of the first RDL 120 exposed via the through holes in the second heat spreader 460. In some examples, the display 480 may have one or more recesses or cavities (not shown) for the disposition of additional active and/or passive devices (not shown).

In some embodiments, an optional connector 490 may be included to connect I-UHDD 400 to other devices and/or circuits. In some examples, the other devices and/or circuits may include a slot in a computing device, an antenna, a battery, a power supply, a bus, and/or the like. In some examples, conductors in connector 490 may be coupled to the conductive lines of the first RDL 460. In some examples, connector 490 is optional and may be omitted.

In some embodiments, other configurations and/or variations of I-UHDD 100 and/or I-UHDD 400 are possible. In some embodiments, I-UHDDs 100 and/or 400 may be adapted to support a two-sided display. FIG. 5 is a simplified diagram of another integrated ultra-high-density device (I-UHDD) 500 according to some embodiments. As shown in FIG. 5, I-UHDD 500 includes several similarities to I-UHDD 100 from FIG. 1 and I-UHDD 400 of FIG. 4, but is adapted to support a two-sided display. Beginning with the same general structure as I-UHDD 400, I-UHDD 500 further includes additional layers and circuitry to support a second display.

As shown in FIG. 5, I-UHDD 500 further includes a second RDL 510 formed on the top of the first heat spreader 450. The second RDL 510 may be consistent with the second RDL 160 of I-UHDD 100. The second RDL 510 includes a network of conductive lines and/or layers of metallization separated by one or more insulating and/or dielectric layers. In some examples, the second RDL 510 may be formed using the methods and/or materials discussed in U.S. Provisional Application Ser. No. 61/952,066, filed Mar. 12, 2014, entitled “Integrated Circuit Assemblies and Methods of Fabrication,” which is hereby incorporated by reference into this application. In some examples, contact pads on the bottom of the second RDL 510 may be electrically coupled to the tops of the posts 410 and/or circuitry in the open-cavity wafer 420 through one or more of the through holes in the first heat spreader 450. In some examples, the bottom of the second RDL 510 may also include one or more dielectric layers to prevent unwanted electrical shorting between the second RDL 510 and the first heat spreader 450.

In some embodiments, an optional non-conductive layer 512 may be formed on the second RDL 510. In some examples, the non-conductive layer 512 may include an underfill material deposited on the second RDL 510. In some examples, the non-conductive layer 512 may include a non-conductive film, dielectric layer, and/or the like formed on the second RDL 510. In some examples, the non-conductive layer 512 may be used to protect the second RDL 510 from accidental electrical shorts, chemical contamination, and/or the like. In some examples, the non-conductive film 512 is optional and may be omitted.

One or more third dies 520 are mounted on the top surface of the second RDL 160. In some examples, the third dies 520 may be mounted to contact pads located on the top surface of the second RDL 510 so that the third dies 520 may be coupled to other circuits in I-UHDD 500 through the conductive lines located in the second RDL 510. In some examples, the third dies 520 may be mounted on the second RDL 510 using a combination of solder balls, bond wires, and/or the like. In some examples, one or more of the third dies 520 may include an image sensor.

A second display 530 is mounted on the non-conductive layer 512. The second display 530 includes a cavity that accommodates the third dies 520. In some examples, electrical signals driving the second display 530 may be provided to the second display 530 using one or more conductors located in the sides of the second display 530. In some examples, the conductors may be coupled to corresponding contact pads of the conductive lines of the second RDL 510 exposed via openings in the non-conductive layer 512. In some examples, when the non-conductive layer 512 is omitted, the second display 530 may be mounted on the second RDL 510. In some examples, the second display 530 may have one or more recesses or cavities (not shown) for the disposition of additional active and/or passive devices (not shown).

In some embodiments, I-UHDD 500 may further include one or more through stiffener conductors (TSCs) 540 passing through holes in the open-cavity wafer 420. In some examples, the TSCs 540 may be formed before or after the first display 480 is attached to the first RDL 120. In some examples, the TSCs 540 may provide one or more electrical conductors for passing signals between the first RDL 120 and the second RDL 510 and/or allow for heat dissipation between the first heat spreader 450 and the second heat spreader 460.

As discussed above and further emphasized here, FIGS. 4 and 5 are merely examples which should not unduly limit the scope of the claims. One of ordinary skill in the art would recognize many variations, alternatives, and modifications. In some embodiments, either or both of the first heat spreader 450 and the second heat spreader 460 may be omitted.

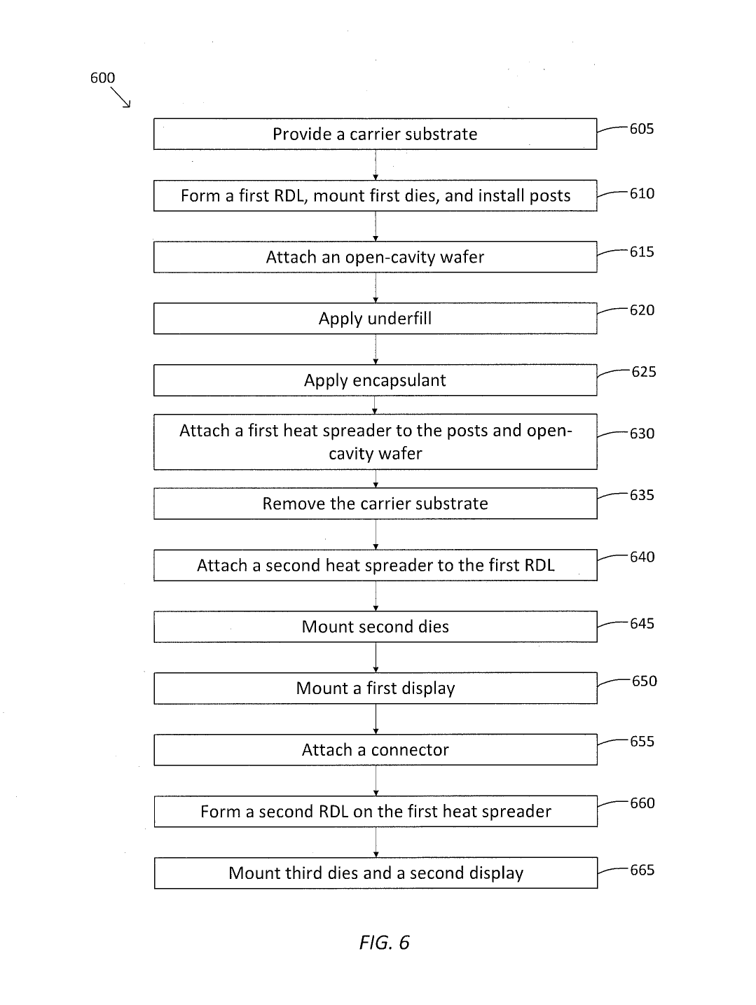

FIG. 6 is a simplified diagram of a method 600 of manufacturing an integrated ultra-high-density device (I-UHDD) according to some embodiments. Processes 605-665 of method 600 are representative only, and one of ordinary skill in the art would understand that variations in processes 605-665 are possible including performing processes 605-665 in different orders, concurrently, and/or the like. In some embodiments, one or more of the processes 620, 625, 655, 660, and/or 665 are optional and may be omitted. In some embodiments, method 600 may be used to manufacture I-UHDD 400 of FIG. 4 and/or I-UHDD 500 of FIG. 5, although one of ordinary skill would understand how method 600 may be applied to form other devices than I-UHDDs 400 and/or 500.

At a process 605, a carrier substrate is provided. In some embodiments, the carrier substrate may be consistent with substrate 110. In some examples, the carrier substrate may be shaped and/or formed using one or more deposition, etching, and/or other semiconductor fabrication techniques. In some examples, the carrier substrate may include any suitable material on which one or more semiconductor devices and/or circuits may be mounted. In some examples, the carrier substrate may include glass, silicon, gallium arsenide, ceramic, composites, and/or the like. In some examples, the carrier substrate may include a rigid and/or semi-rigid material that may provide suitable stiffness and/or physical strength to the I-UHDD. In some examples, the carrier substrate may include one or more materials with a low coefficient of thermal expansion.

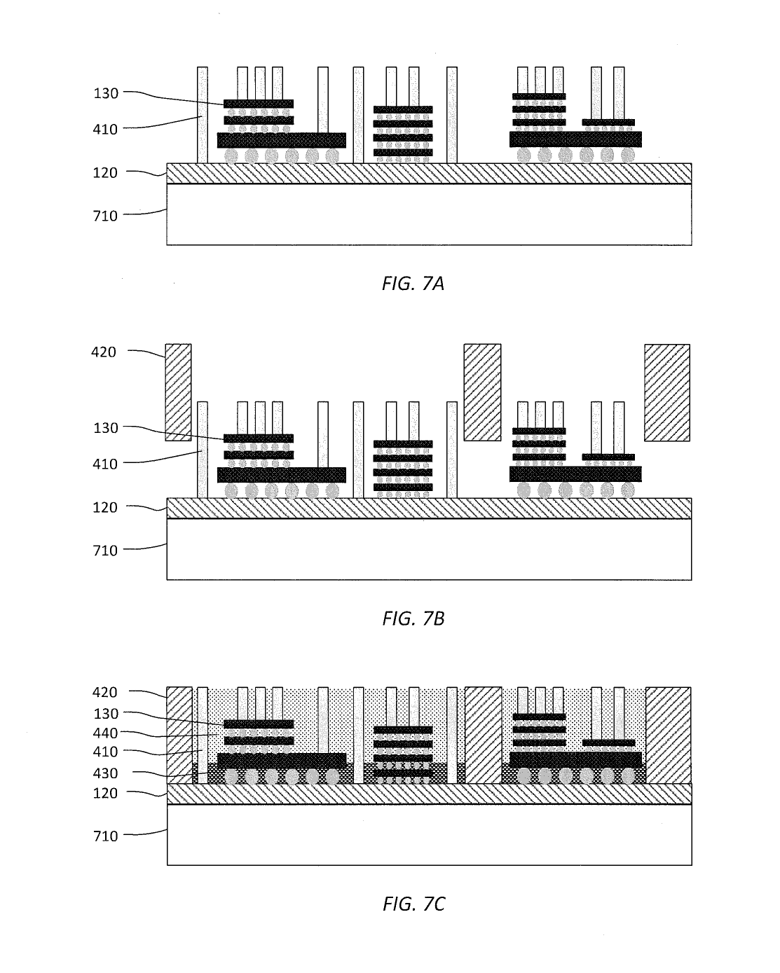

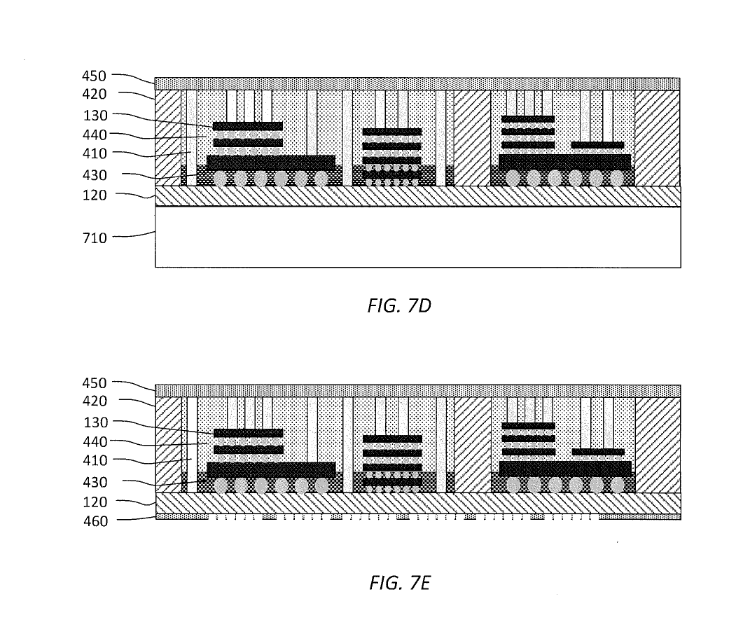

At a process 610, a first RDL is formed, first dies are mounted, and posts are installed. In some embodiments, the first RDL may be consistent with the first RDL 120, the first dies may be consistent with the first dies 130, and the posts may be consistent with posts 410. In some embodiments, one or more of the process 210, 215, and/or 220 may be used to perform process 610. FIG. 7A is a simplified diagram of the partially formed I-UHDD 400 and/or 500 after completion of process 610. FIG. 7A shows the first RDL 120 formed on a carrier substrate 710, one or more first dies 130 mounted and/or stacked on the first RDL 120, and one or more posts 410 installed on the first RDL 120 and/or the stacks of dies 410.

At a process 615, an open-cavity wafer is attached to the first RDL. In some embodiments, the open-cavity wafer may be consistent with open-cavity wafer 420. In some examples, the open-cavity wafer may include one or more through holes to accommodate the locations whether the posts and/or the stacks of dies are mounted to the first RDL. In some examples, the open-cavity wafer may include any suitable wafer material such as glass, silicon, gallium arsenide, and/or the like. In some examples, the open-cavity wafer may have a single cavity and/or multiple cavities. In some examples, the open-cavity wafer may be attached to the first RDL using one or more adhesives and/or bonding processes. In some examples, one or more circuits in the open-cavity wafer may be electrically coupled to contact pads on the first RDL using one or more soldering and/or bonding processes.

FIG. 7B is a simplified diagram of the partially formed I-UHDD 400 and/or 500 during process 615. FIG. 7B shows the open-cavity wafer 420 being moved into position over the first RDL 120 prior to the open-cavity wafer 420 being attached to the first RDL 120.

At an optional process 620, underfill is applied. In some embodiments, the underfill may be consistent with underfill 430. In some embodiments, the underfill may include any suitable underfill material, such as an epoxy resin, an elastomer, and/or the like. In some examples, the underfill may be applied by injection, molding, and/or spin-on coating. In some examples, the underfill may be cured after it is applied.

At an optional process 625, encapsulant is applied. In some embodiments, the encapsulant may be consistent with encapsulant 440. In some examples, the encapsulant may be applied over the posts, the stacked dies, and/or the first RDL. In some examples, the encapsulant may be a flowawable compound, such as an epoxy resin, a polyimide, and/or the like. In some examples, the encapsulant may be a porous compound, such as a porous polyimide and/or the like. In some examples, the encapsulant may be applied by injection, molding, and/or spin-on coating. In some examples, the encapsulant may be cured after it is applied. In some examples, the encapsulant may not completely fill the openings in the open-cavity wafer completely so that at least the top surfaces of the posts are exposed. In some examples, the encapsulant may cover the tops of each of the stacks of dies. In some examples, the upper surface of the encapsulant may be planarized using one or more etching, grinding, and/or CMP processes.

FIG. 7C is a simplified diagram of the partially formed I-UHDD 400 and/or 500 after completion of process 625. FIG. 7C shows the underfill 430 and the encapsulant 440 filling the holes in the open-cavity wafer 420 and surrounding the posts 410, the stacked dies 130, and the first RDL 120.

At a process 630, a first heat spreader is attached to the posts and the open-cavity wafer. In some embodiments, the first heat spreader may be consistent with the first heat spreader 450. In some examples, the first heat spreader may include one or more materials with a high thermal conductivity, such as pyrolytic graphite, HOPG, copper, and/or the like. In some examples, the tops of one or more of the posts and/or the top of the open-cavity wafer may be attached to the first heat spreader using solder, a thermal interface material, and/or one or more thermally conductive adhesives. In some examples, one or more regions of the first heat spreader may also be soldered and/or bonded to respective ones of the posts and/or contact pads on the open-cavity wafer to support electrical conductivity between the respective posts and/or the open-cavity wafer and the regions of the first heat spreader. In some examples, the first heat spreader may further include one or more through holes that may be used to allow one or more of the posts to pass through the first heat spreader to reach circuitry mounted to the opposite side of the first heat spreader.

FIG. 7D is a simplified diagram of the partially formed I-UHDD 400 and/or 500 after completion of process 630. FIG. 7D shows the first heat spreader 450 attached to the top of the posts 410 and the open-cavity wafer 420.

At a process 635, the carrier substrate is removed. In some examples, the carrier substrate 710 may be removed by thinning the carrier substrate 710 until one or more contact pads on the bottom of the first RDL 120 are exposed. In some examples, the thinning may include one or more etching, grinding, and/or CMP processes. In some examples, when the carrier substrate 710 is bonded to the first RDL 120 using one or more adhesives, the carrier substrate 710 may be separated from the first RDL by deactivating the adhesives. In some examples, the adhesives may be deactivated by hardening the adhesives by applying heat, such as through baking and/or use of a laser beam. In some examples, the adhesives may be decoupled between the first RDL 120 and the carrier substrate 710 using ultraviolet radiation. In some examples, once the adhesives lose their adhesion properties, the carrier substrate 710 may be removed.

At a process 640, a second heat spreader is attached to the first RDL. In some examples, the second heat spreader may be consistent with the second heat spreader 460. In some examples, the second heat spreader may include one or more materials with a high thermal conductivity, such as pyrolytic graphite, HOPG, copper, and/or the like. In some examples, the bottom of the first RDL may be attached to the second heat spreader using solder, a thermal interface material, and/or one or more thermally conductive adhesives. In some examples, one or more regions of the second heat spreader may also be soldered and/or bonded to contact pads on the bottom of the first RDL to support electrical conductivity between the conductive lines in the first RDL and the regions of the second heat spreader. In some examples, the second heat spreader may further include one or more through holes that may be used to allow access to one or more contact pads of the first RDL through the second heat spreader.

FIG. 7E is a simplified diagram of the partially formed I-UHDD 400 and/or 500 after completion of process 640. FIG. 7E shows the second heat spreader 460 attached to the bottom of the first RDL 120 as well as the through holes in the second heat spreader 460.

At a process 645, one or more second dies are mounted. In some embodiments, the second dies may be consistent with the second dies 470. In some examples, the second dies may be mounted on the bottom of the first RDL via the through holes in the second heat spreader by using a combination of solder balls, pads, bond wires, and/or the like so that the circuitry on each of the second dies may be electrically interconnected using the network of conductive lines in the first RDL. In some examples, one or more soldering and/or bonding processes may be used to mount the second dies.

At a process 650, a first display is mounted. In some examples, the first display may be consistent with the first display 480. In some examples, the first display 180 may include a cavity that accommodates the second dies. In some examples, electrical signals driving the first display may be provided to first display using one or more conductors located in the sides of first display. In some examples, the conductors may be coupled to corresponding contact pads of the conductive lines of the first RDL exposed via the through holes in the second heat spreader. In some examples, the conductors of the first display may be coupled to the corresponding contact pads using one or more soldering and/or bonding processes.

At an optional process 655, a connector is attached. In some embodiments, the connector may be consistent with the connector 490. In some examples, the connector may be attached to the first RDL using one or more soldering and/or bonding processes so that one or more of the conductive lines in the first RDL may be coupled to other devices and/or circuits, such as a slot in a computing device, an antenna, a battery, a power supply, a bus, and/or the like.

Upon completion of method 655, the I-UHDD 400 may be completed as shown in FIG. 4.

At an optional process 660, a second RDL may be formed on the first heat spreader. In some embodiments, the second RDL may be consistent with the second RDL 510. In some examples, the second RDL may be formed on the first heat spreader using one or more deposition and/or etching processes. In some examples, one or more deposition and/or etching processes may be used to form a network of conductive lines and/or layers of metallization separated by one or more insulating and/or dielectric layers in the second RDL. In some examples, the second RDL may be formed using the methods and/or materials discussed in U.S. Provisional Application Ser. No. 61/952,066, filed Mar. 12, 2014, entitled “Integrated Circuit Assemblies and Methods of Fabrication,” which is hereby incorporated by reference into this application. Additionally, in some embodiments, the tops of one or more of the posts may be structurally, thermally, and/or electrically coupled to the second RDL depending on whether the respective posts are being used for structural, thermal, and/or electrical purposes. In some examples, the tops of the posts may be mounted to one or more bonding pads of the second RDL via the through holes of the first heat spreader. In some examples, solder and/or one or more electrical and/or thermally conductive adhesives may be used to mount the tops of the posts to the second RDL.

In some embodiments, an optional non-conductive layer may be formed on the second RDL. In some embodiments, the non-conductive layer may be consistent with the non-conductive layer 512. In some examples, the non-conductive layer may be deposited on the second RDL in the form of an underfill material. In some examples, one or more non-conductive films, dielectric layers, and/or the like may be formed on the second RDL using one or more deposition and/or etching processes. In some examples, the non-conductive layer may be used to protect the second RDL from accidental electrical shorts, chemical contamination, and/or the like.

At an optional process 665, one or more third dies and/or a second display may be mounted to the second RDL. In some examples, the third dies may be consistent with the third dies 520, and the second display may be consistent with the second display 530. In some embodiments, one or more of the process 240 and/or 245 may be used to perform process 665. Upon completion of method 655, the I-UHDD 500 may be completed as shown in FIG. 5.

Although illustrative embodiments have been shown and described, a wide range of modification, change and substitution is contemplated in the foregoing disclosure and in some instances, some features of the embodiments may be employed without a corresponding use of other features. One of ordinary skill in the art would recognize many variations, alternatives, and modifications. Thus, the scope of the invention should be limited only by the following claims, and it is appropriate that the claims be construed broadly and in a manner consistent with the scope of the embodiments disclosed herein.

What is claimed is:

1. An integrated device, the device comprising:
a first redistribution layer comprising one or more first conductors;
one or more first dies mounted to a first surface of the first redistribution layer and electrically coupled to the first conductors;
one or more first posts having first ends attached to the first dies and second ends opposite the first ends;
one or more second posts having third ends attached to the first surface of the first redistribution layer and fourth ends opposite the third ends; and
a second redistribution layer comprising one or more second conductors, the second redistribution layer being attached to the second ends of the first posts and to the fourth ends of the second posts.

2. The device of claim 1, further comprising an encapsulant between the first redistribution layer and the second redistribution layer, the encapsulant filling space between the first posts, the second posts, and the first dies.

3. The device of claim 1, wherein the first posts comprise one or more metals.

4. The device of claim 1, wherein the first posts thermally couple the first dies and the second redistribution layer and the second posts thermally couple the first redistribution layer and the second redistribution layer.

5. The device of claim 1, wherein the first posts electrically couple the first dies and the second redistribution layer and the second posts electrically couple the first redistribution layer and the second redistribution layer.

6. The device of claim 1, further comprising one or more second dies mounted to the second redistribution layer opposite the first and second posts.

7. The device of claim 1, further comprising a display mounted to the second redistribution layer opposite the first and second posts.

8. The device of claim 1, further comprising a connector electrically coupled to the second conductors for electrically coupling the device to another device.

9. The device of claim 1, further comprising a heat spreader mounted to a second surface of the first redistribution layer, the second surface being opposite the first surface.

10. The device of claim 9, further comprising one or more second dies mounted to the second surface of the first redistribution layer through one or more holes in the heat spreader, the second dies being electrically coupled to the first conductors.

11. The device of claim 1, further comprising a display mounted to a second surface of the first redistribution layer, the second surface being opposite the first surface.

12. The device of claim 1, further comprising a heat spreader mounted between the first posts and the second redistribution layer and between the second posts and the second redistribution layer.

13. The device of claim 1, further comprising an open-cavity wafer located between the first redistribution layer and the second redistribution layer and surrounding the first dies, the first posts, and the second posts.

14. The device of claim 13, further comprising an underfill material and an encapsulant filling open areas of the open-cavity wafer not occupied by the first dies, the first posts, and the second posts.

15. A method of packaging an integrated device, the method comprising:
forming a first redistribution layer comprising one or more first conductors;
mounting one or more first dies to a first surface of the first redistribution layer;
electrically coupling the first dies to the first conductors;
attaching first ends of one or more first posts to the first dies;
attaching second ends of the first posts to a second redistribution layer comprising one or more second conductors, the second ends being opposite the first ends;
attaching third ends of one or more second posts to the first surface of the first redistribution layer;
attaching fourth ends of the second posts to the second redistribution layer, the fourth ends being opposite the third ends;
mounting one or more second dies to the second redistribution layer opposite the first and second posts; and
mounting a display to the second redistribution layer opposite the first and second posts.

16. The method of claim 15, further comprising adding an encapsulant between the first redistribution layer and the second redistribution layer, the encapsulant filling space between the first posts, the second posts, and the first dies.

17. The method of claim 15, further comprising electrically coupling a connector to the second conductors.

18. A method of packaging an integrated device, the method comprising:
forming a first redistribution layer comprising one or more first conductors;
mounting one or more first dies to a first surface of the first redistribution layer;
electrically coupling the first dies to the first conductors;
attaching first ends of one or more first posts to the first dies;
attaching second ends of the first posts to a first heat spreader, the second ends being opposite the first ends;
attaching third ends of one or more second posts to the first surface of the first redistribution layer;
attaching fourth ends of the second posts to the first heat spreader, the fourth ends being opposite the third ends;
locating an open-cavity wafer between the first redistribution layer and the first heat spreader, the open-cavity wafer surrounding the first dies, the first posts, and the second posts;
mounting a second heat spreader to a second surface of the first redistribution layer, the second surface being opposite the first surface;
mounting one or more second dies to the second surface of the first redistribution layer through one or more holes in the first heat spreader;
electrically coupling the second dies to the first conductors; and
mounting a first display to the second surface of the first redistribution layer.

19. The method of claim 18, further comprising filling open areas of the open-cavity wafer not occupied by the first dies, the first posts, and the second posts using an underfill material and an encapsulant.

20. The method of claim 18, further comprising:
forming a second redistribution layer on the first heat spreader opposite the first and second posts, the second redistribution layer comprising one or more second conductors;
mounting one or more third dies to the second redistribution layer opposite the first heat spreader;
electrically coupling the third dies to the first conductors; and
mounting a second display to the second redistribution layer.
